(19) United States
(12) Patent Application Publication
(10) Pub. No.: US 2024/0429194 A1
(43) Pub. Date: Dec. 26, 2024

(54) SEMICONDUCTOR PACKAGE

(71) Applicant: SAMSUNG ELECTRONICS CO, ltd., Suwon-si (KR)

(72) Inventor: EUNSU LEE, Suwon-si (KR)

(21) Appl. No.: 18/610,338

(22) Filed: Mar. 20, 2024

(30) Foreign Application Priority Data
Jun. 21, 2023 (KR) 10-2023-0079814

(51) Int. Cl. H01L 23/00; H01L 23/13; H01L 23/31; H01L 23/433; H01L 25/065

(52) U.S. Cl. CPC H01L 24/26; H01L 23/13; H01L 23/4334; H01L 24/32; H01L 25/0657; H01L 23/3128; H01L 24/16; H01L 24/73; H01L 2224/16227; H01L 2224/26175; H01L 2224/32225; H01L 2224/73204; H01L 2225/06517; H01L 2225/0652; H01L 2225/06548; H01L 2225/06572; H01L 2225/06589

(57) ABSTRACT

A semiconductor package includes a first package substrate, a dam structure on a top surface of the first package substrate and extending and surrounding a region of the first package substrate, a semiconductor chip on the top surface of the first package substrate, a plurality of posts on the top surface of the first package substrate and surrounding the semiconductor chip, and an underfill layer between the semiconductor chip and the first package substrate and surrounding a lower portion of each of the posts, wherein the posts are in the region of the top surface of the first package substrate surrounded by the dam structure.

### CROSS-REFERENCE TO RELATED APPLICATION

This application is based on and claims priority under 35 U.S.C. § 119 to Korean Patent Application No. 10-2023-0079814, filed on Jun. 21, 2023, in the Korean Intellectual Property Office, the disclosure of which is incorporated by reference herein in its entirety.

### BACKGROUND

### 1. Field

Embodiments relate to a semiconductor package, and more particularly, to a package-on-package type semiconductor package.

### 2. Description of the Related Art

With the increase in storage capacity of semiconductor chips, semiconductor packages including a semiconductor chip are required to be thin and light. There has been research into implementing semiconductor chips having various functions in a semiconductor package and quickly driving the semiconductor chips. For example, there has been research into package-on-package type semiconductor packages having a structure in which an upper semiconductor package is mounted on a lower semiconductor package.

### SUMMARY

According to an aspect of embodiments, there is provided a semiconductor package including a first package substrate, a dam structure on a top surface of the first package substrate and extending and surrounding a region of the first package substrate, a semiconductor chip on the top surface of the first package substrate, a plurality of posts on the top surface of the first package substrate and surrounding the semiconductor chip, and an underfill layer between the semiconductor chip and the first package substrate and surrounding a lower portion of each of the posts, wherein the posts are in the region of the top surface of the first package substrate surrounded by the dam structure.

According to another aspect of embodiments, there is provided a semiconductor package including a first package substrate; a dam structure on a top surface of the first package substrate and extending and surrounding a region of the first package substrate, at least one semiconductor chip on the top surface of the first package substrate, a plurality of first posts and a plurality of second posts on the top surface of the first package substrate and surrounding the semiconductor chip, an underfill layer between the semiconductor chip and the first package substrate and surrounding a lower portion of each of the first posts, and a second package substrate on the first posts and the second posts, wherein the first posts are in the region of the top surface of the first package substrate surrounded by the dam structure, the first posts are configured to electrically connect the first package substrate to the second package substrate, and the second posts are configured to physically support the second package substrate.

According to a further aspect of embodiments, there is provided a semiconductor package including a first package substrate, a dam structure on a top surface of the first package substrate and extending and surrounding a region of the first package substrate, at least one lower semiconductor chip on the top surface of the first package substrate, a plurality of first posts and a plurality of second posts on the top surface of the first package substrate and surrounding the lower semiconductor chip, an underfill layer between the at least one lower semiconductor chip and the first package substrate, surrounding a lower portion of each of the first posts, and being in contact with an inner wall of the dam structure, a second package substrate on the first posts and the second posts and including a recessed groove in a bottom surface thereof, and an upper semiconductor chip on the second package substrate, wherein the lower semiconductor chip is vertically below the recessed groove of the second package substrate, the first posts are in the region of the top surface of the first package substrate surrounded by the dam structure, the first posts are configured to electrically connect the first package substrate to the second package substrate, and the second posts are configured to physically support the second package substrate.

### BRIEF DESCRIPTION OF THE DRAWINGS

Features will become apparent to those of skill in the art by describing in detail exemplary embodiments with reference to the attached drawings, in which:

FIG. 1 is a plan view of a semiconductor package according to an embodiment;

FIG. 2 is a cross-sectional view along line A-A′ in FIG. 1;

FIG. 3 is a cross-sectional view along line A-A′ in FIG. 1, according to some embodiments;

FIG. 4 is a cross-sectional view along line A-A′ in FIG. 1, according to some other embodiments;

FIG. 5 is a cross-sectional view along line A-A′ in FIG. 1, according to some other embodiments;

FIG. 6 is a cross-sectional view along line A-A′ in FIG. 1, according to some other embodiments;

FIG. 7 is a plan view of a semiconductor package according to an embodiment;

FIG. 8 is a cross-sectional view along line A1-A1′ in FIG. 7;

FIG. 9 is a plan view of a semiconductor package according to an embodiment; and

FIG. 10 is a cross-sectional view along line A2-A2′ in FIG. 9.

### DETAILED DESCRIPTION

The embodiments may include various modifications and different forms. The detailed description will be set forth with reference to the drawings showing specific embodiments. However, the embodiments will not be restricted to the specific embodiments.

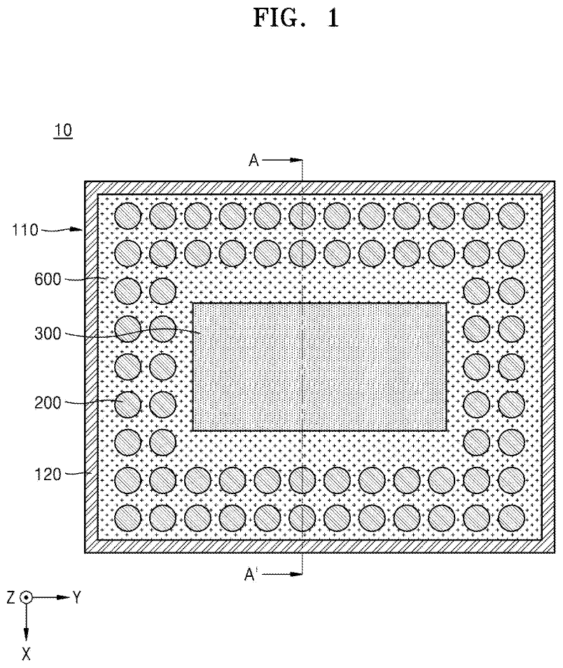

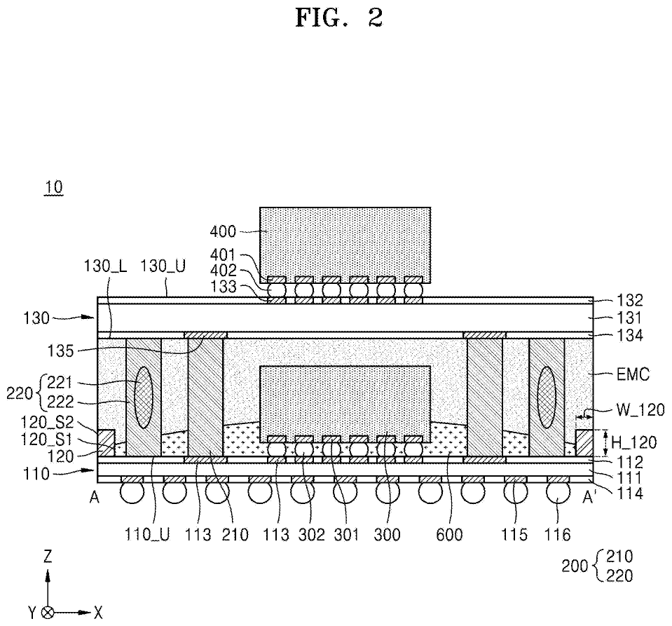

FIG. 1 is a plan view of a semiconductor package 10 according to an embodiment, and FIG. 2 is a cross-sectional view of the semiconductor package 10 of FIG. 1, taken along line A-A′ in FIG. 1. In detail, FIG. 1 is a plan view of the semiconductor package 10, from which a second package substrate 130 and an upper semiconductor chip 400 are omitted.

A package-on-package (POP) type semiconductor package, in which an upper semiconductor package is mounted on a lower semiconductor package, is described with reference to FIGS. 1 and 2. In detail, an interposer-POP (I-POP) type semiconductor package is described below.

Referring to FIGS. 1 and 2, the semiconductor package 10 may include a first package substrate 110, a dam structure 120, a lower semiconductor chip 300, a plurality of posts 200, an underfill layer 600, the second package substrate 130, and the upper semiconductor chip 400.

The first package substrate 110 of the semiconductor package 10 may include a base layer 111, a plurality of upper bump pads 113, a plurality of lower bump pads 115, an upper passivation layer 112, and a lower passivation layer 114. The first package substrate 110 may include a printed circuit board (PCB) or an interposer substrate. The first package substrate 110 may be referred to as a substrate.

The base layer 111 may substantially have a plate shape or a panel shape. The base layer 111 may include a top surface and a bottom surface opposite to the top surface. The top and bottom surface of the base layer 111 may be flat. The top surface of the base layer 111 may face the lower semiconductor chip 300. The base layer 111 may include at least one material of, e.g., phenol resin, epoxy resin, and polyimide. For example, the base layer 111 may include at least one of, e.g., prepreg, polyimide, flame retardant 4 (FR-4), tetrafunctional epoxy, polyphenylene ether, epoxy/polyphenylene oxide, bismaleimide triazine (BT), thermount, cyanate ester, and a liquid crystal polymer.

The upper bump pads 113 may be on the top surface of the base layer 111, and the lower bump pads 115 may be on the bottom surface of the base layer 111. Internal connection wiring configured to electrically connect the upper bump pads 113 to the lower bump pads 115 may be provided in the base layer 111. Each of the upper bump pads 113 and the lower bump pads 115 may include metal, e.g., copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

The upper passivation layer 112 may extend along the top surface of the base layer 111. The upper passivation layer 112 may cover at least a portion of the top surface of the base layer 111 and a portion of at least one of the upper bump pads 113. The upper passivation layer 112 may include upper openings respectively exposing the upper bump pads 113.

The lower passivation layer 114 may extend along the bottom surface of the base layer 111. The lower passivation layer 114 may cover the bottom surface of the base layer 111 and a portion of each of the lower bump pads 115. The lower passivation layer 114 may include lower openings respectively exposing the lower bump pads 115.

The upper passivation layer 112 may include the same material as the lower passivation layer 114. For example, the upper passivation layer 112 and the lower passivation layer 114 may include solder resist.

In embodiments, the thickness of the upper passivation layer 112 may be about 6 μm to about 14 μm. The thickness of the lower passivation layer 114 may be substantially the same as or similar to the thickness of the upper passivation layer 112.

Some of the upper bump pads 113 may be respectively connected to the posts 200. The other upper bump pads 113 may be respectively connected to a plurality of connection terminals 302. Each of the posts 200 and the connection terminals 302 may be in contact with its corresponding one among the upper bump pads 113 through an upper opening of the upper passivation layer 112. The posts 200 may be configured to electrically connect the first package substrate 110 to the second package substrate 130. The connection terminals 302 may be configured to electrically connect the first package substrate 110 to the lower semiconductor chip 300. In some embodiments, the connection terminals 302 may be formed from a solder ball or a solder bump.

The lower bump pads 115 may be respectively connected to external connection terminals 116. Each of the external connection terminals 116 may be in contact with its corresponding one among the lower bump pads 115 through a lower opening of the lower passivation layer 114. The external connection terminals 116 may be configured to electrically and physically connect the first package substrate 110 to an external device and transmit electrical signals between the first package substrate 110 and the external device. The external connection terminals 116 may be formed from a solder ball or a solder bump.

The dam structure 120 of the semiconductor package 10 may be on a top surface 110_U of the first package substrate 110. The dam structure 120 may be arranged to surround a partial region of the first package substrate 110. For example, according to a top view of the semiconductor package 10, the dam structure 120 may have a circular ring shape or a quadrangular ring shape, e.g., to surround an entire perimeter of the first package substrate 110. The dam structure 120 may limit the formation range of the underfill layer 600 by blocking an underfill material from flowing outside the dam structure 120 during an underfill process.

In some embodiments, the dam structure 120 may have a quadrangular ring shape extending along the sides of the top surface 110_U of the first package substrate 110. For example, an outer wall 120_S2 of the dam structure 120 may be coplanar with a sidewall of the first package substrate 110. In other words, the dam structure 120 may vertically overlap four sides of the top surface 110_U of the first package substrate 110.

In some embodiments, a cross-section of the dam structure 120 taken in a direction perpendicular to the extension direction of the dam structure 120 may have a quadrangular shape. A horizontal width of the dam structure 120 in the direction perpendicular to the extension direction of the dam structure 120 may be about 20 μm to about 50 μm. In other words, the distance between an inner wall 120_S1 of the dam structure 120 and the outer wall 120_S2 of the dam structure 120 may be about 20 μm to about 50 μm. The height of the dam structure 120 may be about 10 μm to about 18 μm. In other words, the distance between the bottom and top surfaces of the dam structure 120 may be about 10 μm to about 18 μm.

The dam structure 120 may include an insulating material. For example, the dam structure 120 may include solder resist, epoxy resin, and/or polyimide. In embodiments, the dam structure 120 may include the same material as the upper passivation layer 112. For example, the material of the dam structure 120 and the material of the upper passivation layer 112 may include solder resist. In embodiments, the material of the dam structure 120 may be different from that of the upper passivation layer 112.

The lower semiconductor chip 300 of the semiconductor package 10 may be above the top surface 110_U of the first package substrate 110. The lower semiconductor chip 300 may be in the region of the top surface 110_U of the first package substrate 110 surrounded by the dam structure 120.

The lower semiconductor chip 300 may include a top surface and a bottom surface opposite to the top surface. The bottom surface of the lower semiconductor chip 300 may correspond to an active surface and the top surface of the lower semiconductor chip 300 may correspond to an inactive surface.

In some embodiments, the lower semiconductor chip 300 may be mounted on the first package substrate 110 in a flip chip manner. In other words, the lower semiconductor chip 300 may be arranged on the first package substrate 110 such that the active surface of the lower semiconductor chip 300 faces the first package substrate 110.

For example, the lower semiconductor chip 300 may include silicon (Si). In another example, the lower semiconductor chip 300 may include a semiconductor element, e.g., germanium (Ge), or a compound semiconductor, e.g., silicon carbide (SiC), gallium arsenide (GaAs), indium arsenide (InAs), or indium phosphide (InP).

The lower semiconductor chip 300 may include a conductive region, e.g., an impurity-doped well or an impurity-doped structure. A semiconductor device layer including individual devices may be on the active surface of the lower semiconductor chip 300. For example, the individual devices may include a transistor. The individual devices may include microelectronic devices, e.g., a metal-oxide-semiconductor field effect transistor (MOSFET), a system large scale integration (LSI), an image sensor, e.g., a complementary metal-oxide-semiconductor (CMOS) image sensor (CIS), a micro-electro-mechanical system (MEMS), an active element, and a passive element.

The lower semiconductor chip 300 may further include lower chip pads 301 at the bottom thereof. The lower chip pads 301 may be respectively and electrically connected to the individual devices on the active surface of the lower semiconductor chip 300. The lower chip pads 301 may be electrically connected to the first package substrate 110 respectively through the connection terminals 302.

The lower semiconductor chip 300 may correspond to a memory chip or a logic chip. The memory chip may correspond to a volatile memory semiconductor device including dynamic random access memory (DRAM) or static RAM (SRAM) or a non-volatile memory semiconductor device including phase-change RAM (PRAM), magnetoresistive RAM (MRAM), ferroelectric RAM (FeRAM), or resistive RAM (RRAM). The logic chip may include a central processing unit (CPU) chip, a graphics processing unit (GPU) chip, an application processor (AP) chip, or an application specific integrated circuit (ASIC) chip.

The posts 200 of the semiconductor package 10 may be on the top surface 110_U of the first package substrate 110. The posts 200 may be arranged to surround the lower semiconductor chip 300. For example, the posts 200 may be separated from each other near the side surface of the lower semiconductor chip 300. In some embodiments, the posts 200 may be arranged in three rows near two side surfaces separated in the X direction among four side surfaces of the lower semiconductor chip 300 and one row near the two side surfaces separated in the Y direction among the four side surfaces of the lower semiconductor chip 300. As shown in FIG. 2, the posts 200 may be arranged in two rows near each of the four side surfaces of the lower semiconductor chip 300.

The posts 200 may be in a region of the top surface 110_U of the first package substrate 110 surrounded by the dam structure 120. In other words, the posts 200 may be inside the dam structure 120, e.g., the posts 200 may be between the dam structure 120 and the lower semiconductor chip 300 along a perimeter of the lower semiconductor chip 300. The dam structure 120 may surround the posts 200 and the lower semiconductor chip 300. The underfill layer 600 may surround a lower portion of each of the posts 200 because the underfill layer 600 is formed in a region surrounded by the dam structure 120 during an underfill process. The underfill layer 600 may protect a contact portion between each of the post 200 and the first package substrate 110 by surrounding (e.g., directly contacting and completely surrounding) the lower portion of each post 200, and accordingly, failure of the semiconductor package 10 may be prevented.

The bottom surface of each of the posts 200 may be in contact with the first package substrate 110 and the top surface thereof may be in contact with the second package substrate 130. The posts 200 may support the second package substrate 130 such that the second package substrate 130 is separated from the first package substrate 110.

The posts 200 may include a plurality of first posts 210 and a plurality of second posts 220. The first posts 210 may be configured to electrically connect the first package substrate 110 to the second package substrate 130, and the second posts 220 may be configured to physically support the second package substrate 130.

Each of the first posts 210 may be in contact (e.g., direct contact) with one of the upper bump pads 113 of the first package substrate 110 and a lower bump pad 135 of the second package substrate 130, and may electrically connect the first package substrate 110 to the second package substrate 130. In some embodiments, the first posts 210 may include at least one of a Cu post and a solder ball. In other words, the first posts 210 may include a conductive material.

Each of the second posts 220 may include a core layer 221 and a solder layer 222 surrounding the core layer 221. For example, the core layer 221 may include Cu. In an embodiment, the solder layer 222 may include conductive solder. For example, the solder layer 222 may include at least one of Sn, silver (Ag), and Cu.

The second posts 220 may be in contact (e.g., direct contact) with the top surface 110_U of the first package substrate 110 and a bottom surface 130_L of the second package substrate 130. When the second posts 220 are between the first package substrate 110 and the second package substrate 130, the gap between the first package substrate 110 and the second package substrate 130 may be maintained (e.g., may be constant). Accordingly, the warpage of the semiconductor package 10 may be prevented, and thus, the structural reliability of the semiconductor package 10 may increase.

In some embodiments, the first posts 210 and the second posts 220 may be in a region of the first package substrate 110 surrounded by the dam structure 120. The underfill layer 600 may surround a lower portion of each of the second posts 220 as well as a lower portion of each of the first posts 210.

The underfill layer 600 of the semiconductor package 10 may be on (e.g., directly on) the top surface 110_U of the first package substrate 110. For example, the underfill layer 600 may be between the first package substrate 110 and the lower semiconductor chip 300. In some embodiments, the underfill layer 600 may cover a portion of a side surface of the lower semiconductor chip 300. The underfill layer 600 may surround a lower portion of each of the posts 200, e.g., the underfill layer 600 may completely surround a lower portion of each of the posts 200 that is adjacent to the top surface 110_U of the first package substrate 110. The underfill layer 600 may be in contact (e.g., direct contact) with the inner wall 120_S1 of the dam structure 120.

In detail, the underfill layer 600 may be formed to fill a region above the top surface 110_U of the first package substrate 110 surrounded by the dam structure 120 such that the underfill layer 600 may be in contact with the inner wall 120_S1 of the dam structure 120 and may surround a portion of the lower semiconductor chip 300 and a lower portion of each of some posts 200.

In some embodiments, the underfill layer 600 may surround a contact portion between each of the first posts 210 and its corresponding one among the upper bump pads 113 of the first package substrate 110. For example, the underfill layer 600 may be near the upper openings of the upper passivation layer 112. The underfill layer 600 may surround a contact portion between each of the first posts 210 and its corresponding one among the upper bump pads 113 of the first package substrate 110. For example, as illustrated in FIG. 2, the underfill layer 600 may directly contact an entire perimeter of the lower lateral sidewall of the first post 210, a portion of an upper surface of the upper bump pad 113 facing the first posts 210, and the upper surface of the upper passivation layer 112. Thus, the underfill layer 600 may suppress cracks from occurring between the first posts 210 and the upper bump pads 113 of the first package substrate 110.

The second package substrate 130 of the semiconductor package 10 may be above the lower semiconductor chip 300 and the posts 200. In detail, the second package substrate 130 may be mounted on the top surfaces of the posts 200 and may be separated (e.g., by a space) from the lower semiconductor chip 300 in the vertical direction (the Z direction).

The second package substrate 130 may include a base layer 131, a plurality of upper bump pads 133, a plurality of lower bump pads 135, an upper passivation layer 132, and a lower passivation layer 134. The second package substrate 130 may include a PCB or an interposer substrate. The second package substrate 130 may be referred to as a substrate. The base layer 131 may include an interposer.

The base layer 131, the upper bump pads 133, the lower bump pads 135, the upper passivation layer 132, and the lower passivation layer 134 of the second package substrate 130 may be substantially similar to the base layer 111, the upper bump pads 113, the lower bump pads 115, the upper passivation layer 112, and the lower passivation layer 114 of the first package substrate 110, and thus, differences therebetween are mainly described.

The upper bump pads 133 may be respectively connected to a plurality of connection terminals 402. Each of the connection terminals 402 may be connected to its corresponding one among the upper bump pads 133 through an upper opening of the upper passivation layer 132. The connection terminals 402 may be configured to electrically connect the second package substrate 130 to the upper semiconductor chip 400. In some embodiments, the connection terminals 402 may be formed from a solder ball or a solder bump.

The lower bump pads 135 may be respectively connected to a plurality of posts 200. Each of the posts 200 (i.e., each of the first posts 210) may be in contact with its corresponding one among the lower bump pads 135 through a lower opening of the lower passivation layer 134. The posts 200 (i.e., the first posts 210) may be configured to physically and electrically connect the first package substrate 110 to the second package substrate 130.

The semiconductor package 10 may further include a molding layer EMC. The molding layer EMC may fill between the first package substrate 110 and the second package substrate 130 and surround the lower semiconductor chip 300. In an embodiment, the molding layer EMC may fill between the top surface of the lower semiconductor chip 300 and the bottom surface 130_L of the second package substrate 130 such that the lower semiconductor chip 300 is separated from the second package substrate 130. For example, the molding layer EMC may include an epoxy molding compound. For example, as illustrated in FIG. 2, the molding layer EMC may be in direct contact with an upper surface of the underfill layer 600.

The upper semiconductor chip 400 of the semiconductor package 10 may be on a top surface 130_U of the second package substrate 130. The upper semiconductor chip 400 may be mounted on the second package substrate 130 in a flip chip manner.

The upper semiconductor chip 400 may include a top surface and a bottom surface opposite to the top surface. The bottom surface of the upper semiconductor chip 400 may correspond to an active surface and the top surface of the upper semiconductor chip 400 may correspond to an inactive surface.

For example, the upper semiconductor chip 400 may include Si. In another example, the upper semiconductor chip 400 may include a semiconductor element, e.g., Ge, or a compound semiconductor, e.g., SiC, GaAs, InAs, or InP.

The upper semiconductor chip 400 may include a conductive region, e.g., an impurity-doped well or an impurity-doped structure. A semiconductor device layer including individual devices may be on the active surface of the upper semiconductor chip 400. For example, the individual devices may include a transistor. The individual devices may include microelectronic devices, e.g., a MOSFET, a system LSI, an image sensor, e.g., a CIS, an MEMS, an active element, and a passive element.

The upper semiconductor chip 400 may further include lower chip pads 401 at the bottom thereof. The lower chip pads 401 may be respectively and electrically connected to the individual devices on the active surface of the upper semiconductor chip 400.

The upper semiconductor chip 400 may correspond to a memory chip or a logic chip. The memory chip may correspond to a volatile memory semiconductor device including DRAM or SRAM or a non-volatile memory semiconductor device including PRAM, MRAM, FeRAM, or RRAM. The logic chip may include a CPU chip, a GPU chip, an AP chip, or an ASIC chip.

In some embodiments, the lower semiconductor chip 300 may be of a different type than the upper semiconductor chip 400. For example, the lower semiconductor chip 300 may be a logic chip and the upper semiconductor chip 400 may be a memory chip.

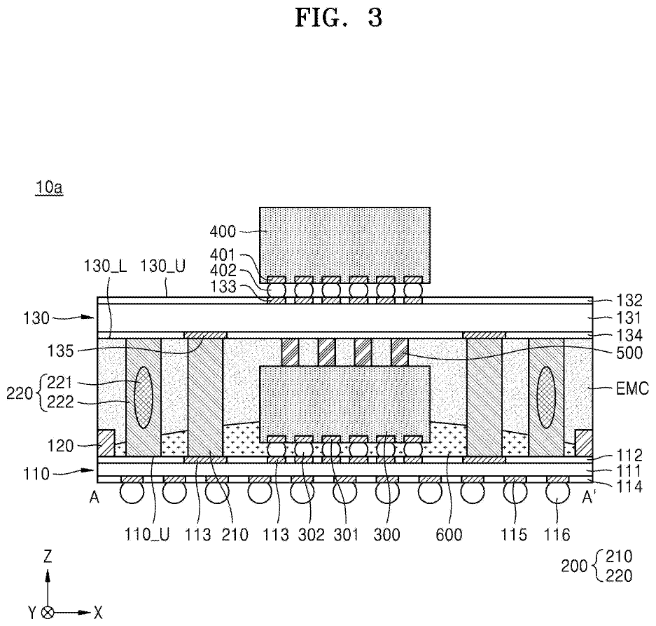

FIG. 3 is a cross-sectional view of a semiconductor package 10a taken along line A-A′ in FIG. 1, according to some embodiments.

Referring to FIG. 3, the semiconductor package 10a may include the first package substrate 110, the dam structure 120, the lower semiconductor chip 300, the plurality of posts 200, the underfill layer 600, the second package substrate 130, and the upper semiconductor chip 400. Repetitive descriptions relative to the semiconductor package 10 of FIG. 2 are omitted, and differences between the semiconductor package 10 and semiconductor package 10a are mainly described below.

In detail, the semiconductor package 10a may further include a heat dissipation pillar 500. The heat dissipation pillar 500 may be on the top surface of the lower semiconductor chip 300. In some embodiments, the heat dissipation pillar 500 may be in contact (e.g., direct contact) with the bottom surface 130_L of the second package substrate 130. The heat dissipation pillar 500 may provide a path, through which heat generated in the lower semiconductor chip 300 is discharged to the outside of the semiconductor package 10a. In particular, the heat dissipation pillar 500 may provide a path, through which heat generated in the lower semiconductor chip 300 is discharged to the outside of the semiconductor package 10a via the second package substrate 130.

For example, as illustrated in FIG. 3, the horizontal width of the heat dissipation pillar 500 may be constant with respect to a vertical level. In another example, the horizontal width of the heat dissipation pillar 500 may vary with a vertical level, e.g., the horizontal width of the heat dissipation pillar 500 may increase toward the second package substrate 130.

The semiconductor package 10a may efficiently discharge heat, which is generated in the lower semiconductor chip 300, through the heat dissipation pillar 500.

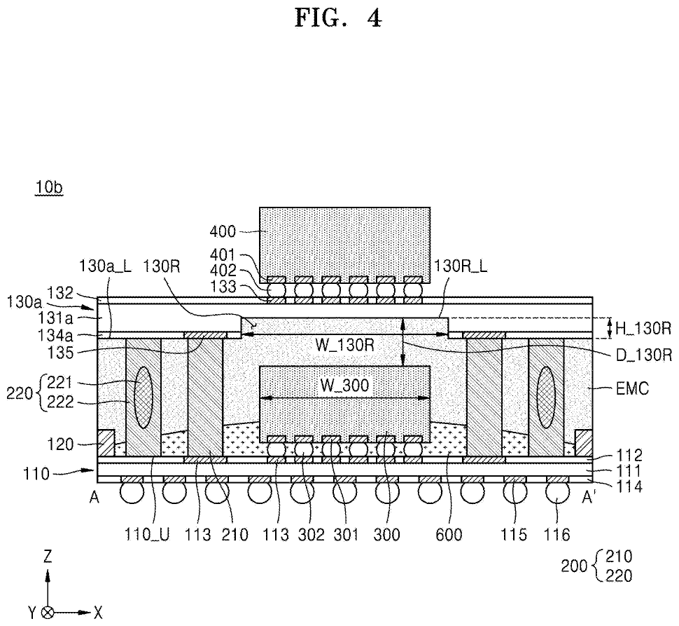

FIG. 4 is a cross-sectional view of a semiconductor package 10b taken along line A-A′ in FIG. 1, according to some embodiments.

Referring to FIG. 4, the semiconductor package 10b may include the first package substrate 110, the dam structure 120, the lower semiconductor chip 300, the plurality of posts 200, the underfill layer 600, a second package substrate 130a, and the upper semiconductor chip 400. Repetitive descriptions relative to the semiconductor package 10 of FIG. 2 are omitted, and differences between the semiconductor package 10 and the semiconductor package 10b of FIG. 4 are mainly described below.

In detail, the second package substrate 130a of the semiconductor package 10b may include a recessed groove 130R. The recessed groove 130R may be formed by recessing a bottom surface 130a_L of the second package substrate 130a. In some embodiments, the recessed groove 130R may extend from the bottom surface 130a L of the second package substrate 130a toward the top surface of the second package substrate 130a. In detail, a base layer 131a and a lower passivation layer 134a of the second package substrate 130a may include the recessed groove 130R partially passing therethrough.

The recessed groove 130R may be above the lower semiconductor chip 300. In other words, the recessed groove 130R may overlap the lower semiconductor chip 300 in the vertical direction (the Z direction). The lower semiconductor chip 300 may be separated from the recessed groove 130R in the vertical direction (the Z direction).

In detail, a bottom 130R_L of the recessed groove 130R may be separated from the top surface of the lower semiconductor chip 300 in the vertical direction (the Z direction). The bottom 130R_L of the recessed groove 130R may correspond to a recessed portion of the bottom surface 130a_L of the second package substrate 130a. The bottom 130R_L of the recessed groove 130R may be referred to as a ceiling of the recessed groove 130R. The recessed groove 130R may be filled with the molding layer EMC. The molding layer EMC may be between the bottom 130R_L of the recessed groove 130R and the lower semiconductor chip 300.

In some embodiments, a distance D_130R between the bottom 130R_L of the recessed groove 130R and the top surface of the lower semiconductor chip 300 may be about 40 μm to about 70 μm. A height H_130R, by which the bottom surface 130a L of the second package substrate 130a is recessed, may be about 10 μm to about 20 μm.

In some embodiments, a horizontal distance W_130R between opposite sidewalls of the recessed groove 130R may be greater than a horizontal length W_300 of the lower semiconductor chip 300. The horizontal area of the recessed portion of the bottom surface 130a_L of the second package substrate 130a may be greater than the area of the top surface of the lower semiconductor chip 300.

When the semiconductor package 10b includes the recessed groove 130R in the second package substrate 130a, the thickness of the lower semiconductor chip 300 may be increased while the thickness of the semiconductor package 10b is maintained. When the thickness of the lower semiconductor chip 300 increases, the heat dissipation performance of the lower semiconductor chip 300 may also increase.

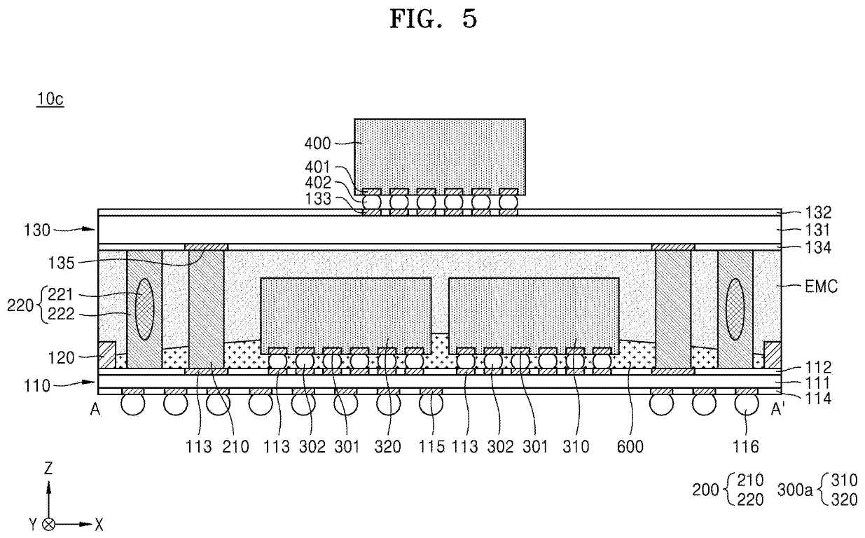

FIG. 5 is a cross-sectional view of a semiconductor package 10c taken along line A-A′ in FIG. 1, according to some embodiments.

Referring to FIG. 5, the semiconductor package 10c may include the first package substrate 110, the dam structure 120, at least one lower semiconductor chip 300a, the plurality of posts 200, the underfill layer 600, the second package substrate 130, and the upper semiconductor chip 400. Repetitive descriptions relative to the semiconductor package 10 of FIG. 2 are omitted, and differences between the semiconductor package 10 and the semiconductor package 10c of FIG. 5 are mainly described below.

In detail, the at least one lower semiconductor chip 300a of the semiconductor package 10c may include a first lower semiconductor chip 310 and a second lower semiconductor chip 320. In some embodiments, each of the first lower semiconductor chip 310 and the second lower semiconductor chip 320 may be substantially the same as the lower semiconductor chip 300 described above with reference to FIG. 2. For example, the first lower semiconductor chip 310 may be of the same type as the second lower semiconductor chip 320. In another example, the first lower semiconductor chip 310 may be of a different type than the second lower semiconductor chip 320.

The first lower semiconductor chip 310 and the second lower semiconductor chip 320 may be arranged alongside each other on the top surface of the first package substrate 110. In other words, the first lower semiconductor chip 310 and the second lower semiconductor chip 320 may be separated from each other in a horizontal direction. In some embodiments, the first lower semiconductor chip 310 may be electrically connected to the second lower semiconductor chip 320 through internal wiring of the first package substrate 110.

The posts 200 may be arranged to surround the first lower semiconductor chip 310 and the second lower semiconductor chip 320. For example, as illustrated in FIG. 5, there are no posts 200 between the first lower semiconductor chip 310 and the second lower semiconductor chip 320. In another example, there may be some posts 200 between the first lower semiconductor chip 310 and the second lower semiconductor chip 320.

Although not shown in FIG. 5, the second package substrate 130 may include a recessed groove (similarly to the recessed groove 130R of FIG. 4). The horizontal area of the recessed groove in the bottom surface of the second package substrate 130 may be greater than the sum of the respective horizontal areas of the first lower semiconductor chip 310 and the second lower semiconductor chip 320.

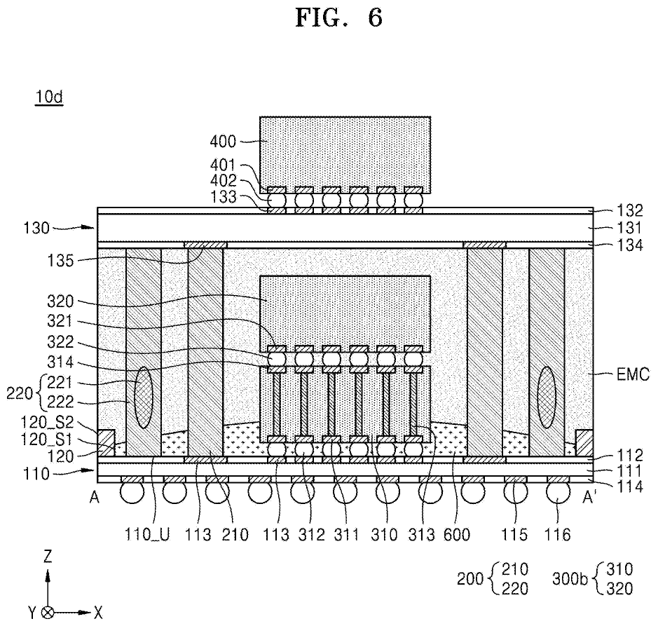

FIG. 6 is a cross-sectional view of a semiconductor package 10d taken along line A-A′ in FIG. 1, according to some embodiments.

Referring to FIG. 6, the semiconductor package 10d may include the first package substrate 110, the dam structure 120, at least one lower semiconductor chip 300b, the plurality of posts 200, the underfill layer 600, the second package substrate 130a, and the upper semiconductor chip 400. Repetitive descriptions relative to the semiconductor package 10 of FIG. 2 are omitted, and differences between the semiconductor package 10 and the semiconductor package 10d of FIG. 6 are mainly described below.

In detail, the at least one lower semiconductor chip 300b of the semiconductor package 10d may include the first lower semiconductor chip 310 and the second lower semiconductor chip 320. In some embodiments, the first lower semiconductor chip 310 and the second lower semiconductor chip 320 in FIG. 6 may be substantially the same as the first lower semiconductor chip 310 and the second lower semiconductor chip 320 in FIG. 5.

The second lower semiconductor chip 320 may be stacked on the first lower semiconductor chip 310 in the vertical direction (the Z direction). For example, the first lower semiconductor chip 310 may be on the first package substrate 110 and the second lower semiconductor chip 320 may be on the first lower semiconductor chip 310. In other words, the second lower semiconductor chip 320 may overlap the first lower semiconductor chip 310 in the vertical direction (the Z direction).

The first lower semiconductor chip 310 may be electrically connected to the first package substrate 110 through a bottom chip pad 311 and a connection terminal 312. The first lower semiconductor chip 310 may further include a top chip pad 314 and a through via 313, which passes through the first lower semiconductor chip 310 and connects the top chip pad 314 to the bottom chip pad 311. The second lower semiconductor chip 320 may be electrically connected to the first package substrate 110 through a bottom chip pad 321, a connection terminal 322, and the first lower semiconductor chip 310.

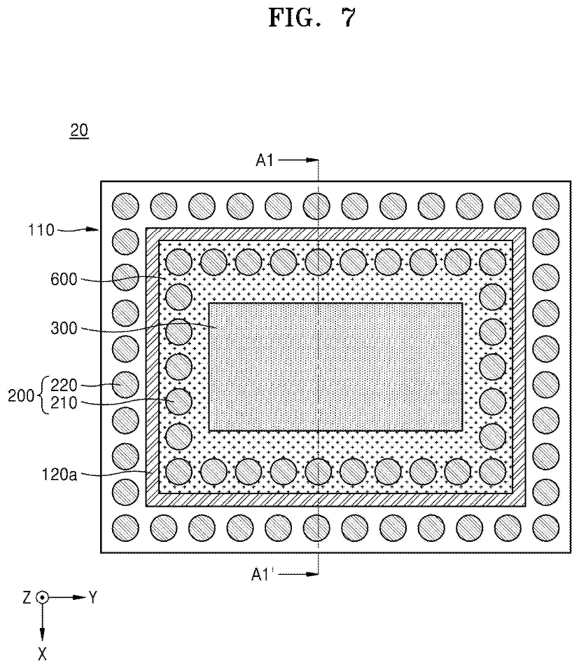

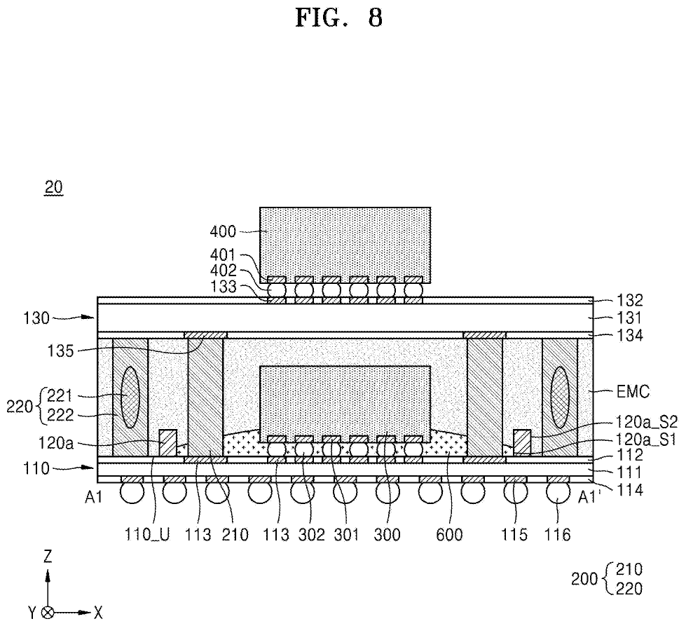

FIG. 7 is a plan view of a semiconductor package 20 according to an embodiment. FIG. 8 is a cross-sectional view of the semiconductor package 20 of FIG. 7, taken along line A1-A1′ in FIG. 7. In detail, FIG. 7 is a plan view of the semiconductor package 20, from which the second package substrate 130 and the upper semiconductor chip 400 are omitted.

Referring to FIGS. 7 and 8, the semiconductor package 20 may include the first package substrate 110, a dam structure 120a, the lower semiconductor chip 300, the plurality of posts 200, the underfill layer 600, the second package substrate 130, and the upper semiconductor chip 400. Repetitive descriptions relative to the semiconductor package 10 of FIG. 2 are omitted, and differences between the semiconductor package 10 and the semiconductor package 20 of FIG. 8 are mainly described below.

In detail, the semiconductor package 20 of FIG. 8 is different from the semiconductor package 10 of FIG. 2 in the dam structure 120a. Thus, the dam structure 120a is described in detail.

The dam structure 120a of the semiconductor package 20 may be on the top surface 110_U of the first package substrate 110. The dam structure 120a may be arranged to surround a region (e.g., a partial region) of the first package substrate 110. For example, according to a top view of the semiconductor package 20, the dam structure 120a may have a circular ring shape or a quadrangular ring shape.

The dam structure 120a may be spaced apart from the edge of the first package substrate 110. For example, an outer wall 120a_S2 of the dam structure 120a may be on the top surface 110_U of the first package substrate 110 but not coplanar with a sidewall of the first package substrate 110.

In some embodiments, the dam structure 120a may be spaced apart from four sides of the top surface 110_U of the first package substrate 110 with some of the posts 200 between the dam structure 120a and the four sides of the top surface 110_U of the first package substrate 110. In some embodiments, the dam structure 120a may be between a plurality of first posts 210 and a plurality of second posts 220. The first posts 210 may be in a region of the top surface 110_U of the first package substrate 110 surrounded by the dam structure 120a and the second posts 220 may be in a region of the top surface 110_U of the first package substrate 110 outside the dam structure 120a.

In some embodiments, the underfill layer 600 may be formed inside the dam structure 120a such that an inner wall 120a_S1 of the dam structure 120a is in contact with the underfill layer 600. The outer wall 120a_S2 of the dam structure 120a may be in contact with the molding layer EMC. For example, the first posts 210 may be inside the dam structure 120a and the underfill layer 600 may surround a lower portion of each of the first posts 210. The second posts 220 may be outside the dam structure 120a and the underfill layer 600 may not surround a lower portion of the second posts 220.

The underfill layer 600 may protect the lower portion of each of the first posts 210, which electrically connect the first package substrate 110 to the second package substrate 130, from an external impact. Accordingly, cracks may be suppressed from occurring between the first posts 210 and the upper bump pads 113 of the first package substrate 110.

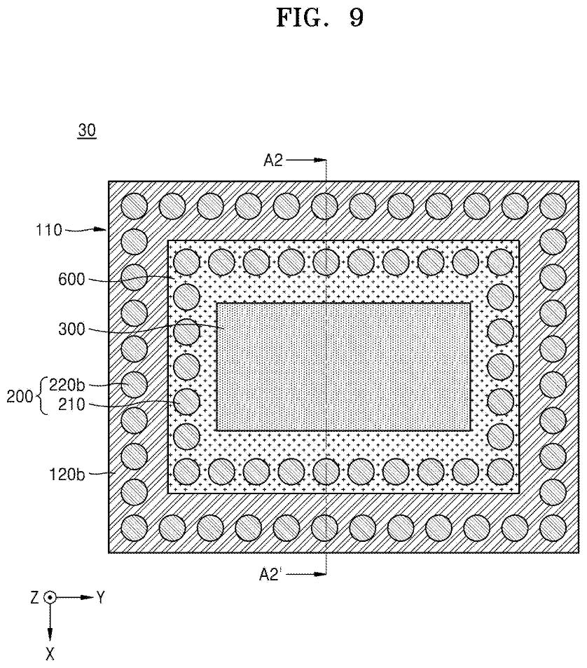

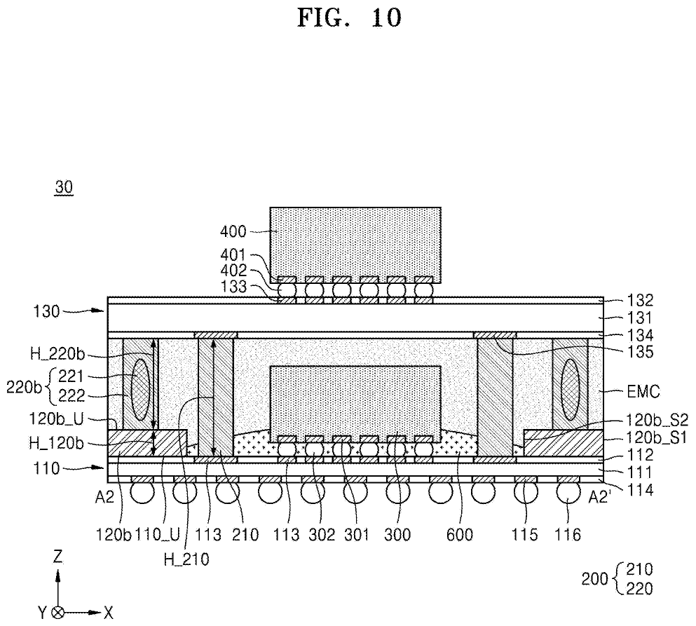

FIG. 9 is a plan view of a semiconductor package 30 according to an embodiment. FIG. 10 is a cross-sectional view of the semiconductor package 30 of FIG. 9, taken along line A2-A2′ in FIG. 9. In detail, FIG. 9 is a plan view of the semiconductor package 30, from which the second package substrate 130 and the upper semiconductor chip 400 are omitted.

Referring to FIGS. 9 and 10, the semiconductor package 30 may include the first package substrate 110, a dam structure 120b, the lower semiconductor chip 300, the plurality of posts 200, the underfill layer 600, the second package substrate 130, and the upper semiconductor chip 400. Repetitive descriptions relative to the semiconductor package 10 of FIG. 2 are omitted, and differences between the semiconductor package 10 and the semiconductor package 30 of FIG. 10 are mainly described below.

The semiconductor package 30 of FIG. 10 is different from the semiconductor package 10 of FIG. 2 in the dam structure 120b. Thus, the dam structure 120b is described in detail.

The dam structure 120b of the semiconductor package 30 may be on the top surface 110_U of the first package substrate 110. The dam structure 120b may be arranged to surround a partial region of the first package substrate 110. The dam structure 120b may surround a portion of the first package substrate 110. The dam structure 120b may block an underfill material from flowing outside the dam structure 120b during an underfill process and the underfill layer 600 may be in contact with an inner wall 120b_S1 of the dam structure 120b.

A plurality of first posts 210 may be in a region of the top surface 110_U of the first package substrate 110 surrounded by the dam structure 120b. A plurality of second posts 220b may be on a top surface 120b_U of the dam structure 120b. A horizontal width of a cross-section of the dam structure 120b taken in a direction perpendicular to the extension direction of the dam structure 120b may be greater than a horizontal width of each of the second posts 220b.

In some embodiments, a height H_210 of each of the first posts 210 may be different from a height H_220b of each of the second posts 220b. The first posts 210 may be on the top surface 110_U of the first package substrate 110 such that the height H_210 of each of the first posts 210 may be substantially the same as the distance between the top surface 110_U of the first package substrate 110 and the bottom surface 130_L of the second package substrate 130. The second posts 220b may be on the top surface 120b_U of the dam structure 120b such that the height H_220b of each of the second posts 220b may be substantially the same as the distance between the top surface 120b U of the dam structure 120b and the bottom surface 130_L of the second package substrate 130. For example, the height H_220b of the second posts 220b may be less than the height H_210 of the first posts 210 by a height H_120b of the dam structure 120b.

In some embodiments, an outer wall 120b_S2 of the dam structure 120b may be coplanar with a sidewall of the first package substrate 110. The dam structure 120b may have a plate shape including a hole, in which the lower semiconductor chip 300 and the first posts 210 are located. For example, as illustrated in FIG. 10, the outer wall 120b S2 of the dam structure 120b is coplanar with a sidewall of the first package substrate 110. In another example, the outer wall 120b_S2 of the dam structure 120b may be spaced apart from the edge of the first package substrate 110.

The underfill layer 600 may protect the lower portion of each of the first posts 210, which electrically connect the first package substrate 110 to the second package substrate 130, from an external impact. Accordingly, cracks may be suppressed from occurring between the first posts 210 and the upper bump pads 113 of the first package substrate 110.

By way of summation and review, embodiments provide a package-on-package type semiconductor package suppressing cracks from occurring in a contact portion of a post that connects an upper package substrate to a lower package substrate. Embodiments also provide a package-on-package type semiconductor package in which a semiconductor chip is thick and thus has a high heat dissipation performance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a first package substrate;
a dam structure on a top surface of the first package substrate, the dam structure extending and surrounding a region of the first package substrate;
a semiconductor chip on the top surface of the first package substrate;
a plurality of posts on the top surface of the first package substrate and surrounding the semiconductor chip, the plurality of posts being in the region of the top surface of the first package substrate surrounded by the dam structure; and
an underfill layer between the semiconductor chip and the first package substrate, the underfill layer surrounding a lower portion of each of the plurality of posts.

2. The semiconductor package as claimed in claim 1, wherein:
the dam structure has a quadrangular ring shape extending along sides of the top surface of the first package substrate, and
a horizontal width of the dam structure in a direction that is perpendicular to an extension direction of the dam structure is about 20 μm to about 50 μm.

3. The semiconductor package as claimed in claim 1, wherein a height of the dam structure in a vertical direction is about 10 μm to about 18 μm.

4. The semiconductor package as claimed in claim 1, wherein:
the first package substrate includes a plurality of upper bump pads on the top surface thereof,
some of the plurality of posts are in contact with respective ones of the plurality of upper bump pads, and
the underfill layer surrounds contact portions between the plurality of posts and the respective ones of the plurality of upper bump pads.

5. The semiconductor package as claimed in claim 1, wherein the underfill layer is in the region of the top surface of the first package substrate surrounded by the dam structure, the underfill layer being in contact with an inner wall of the dam structure.

6. The semiconductor package as claimed in claim 1, further comprising a heat dissipation pillar on a top surface of the semiconductor chip.

7. The semiconductor package as claimed in claim 1, further comprising a second package substrate above the semiconductor chip and the plurality of posts and including an interposer.

8. The semiconductor package as claimed in claim 7, wherein the second package substrate further includes a recessed groove in a bottom surface thereof.

9. The semiconductor package as claimed in claim 8, wherein a horizontal distance between opposite side walls of the recessed groove is greater than a horizontal length of the semiconductor chip, the semiconductor chip being vertically below the recessed groove.

10. The semiconductor package as claimed in claim 9, wherein:
a height of the recessed groove from the bottom surface of the second package substrate is about 10 μm to about 20 μm, and
a distance between a top surface of the semiconductor chip and a bottom of the recessed groove in a vertical direction is about 40 μm to about 70 μm.

11. The semiconductor package as claimed in claim 7, wherein a portion of the plurality of posts electrically connect the first package substrate to the second package substrate.

12. The semiconductor package as claimed in claim 11, wherein the portion of the plurality of posts that electrically connect the first package substrate to the second package substrate includes at least one of a copper post and a solder ball.

13. A semiconductor package, comprising:
a first package substrate;
a dam structure on a top surface of the first package substrate, the dam structure extending and surrounding a region of the first package substrate;
at least one semiconductor chip on the top surface of the first package substrate;
a plurality of first posts and a plurality of second posts on the top surface of the first package substrate and surrounding the at least one semiconductor chip;
an underfill layer between the at least one semiconductor chip and the first package substrate and surrounding a lower portion of each of the plurality of first posts; and
a second package substrate on the plurality of first posts and the plurality of second posts,
wherein:
the plurality of first posts are in the region of the top surface of the first package substrate surrounded by the dam structure,
the plurality of first posts electrically connect the first package substrate to the second package substrate, and
the plurality of second posts physically support the second package substrate.

14. The semiconductor package as claimed in claim 13, wherein:
the plurality of second posts are in the region of the top surface of the first package substrate surrounded by the dam structure, and
the underfill layer surrounds a lower portion of each of the plurality of second posts.

15. The semiconductor package as claimed in claim 13, wherein the plurality of second posts are on a top surface of the dam structure.

16. The semiconductor package as claimed in claim 13, wherein:
the at least one semiconductor chip includes a first lower semiconductor chip and a second lower semiconductor chip, and
the first lower semiconductor chip and the second lower semiconductor chip are arranged alongside each other on the first package substrate.

17. The semiconductor package as claimed in claim 13, wherein:
the at least one semiconductor chip includes a first lower semiconductor chip and a second lower semiconductor chip,
the first lower semiconductor chip is on the first package substrate, and
the second lower semiconductor chip is on the first lower semiconductor chip.

18. The semiconductor package as claimed in claim 13, further comprising a molding layer filling between the first package substrate and the second package substrate and surrounding the at least one semiconductor chip.

19. A semiconductor package, comprising:
a first package substrate;
a dam structure on a top surface of the first package substrate, the dam structure extending and surrounding a region of the first package substrate;
at least one lower semiconductor chip on the top surface of the first package substrate;
a plurality of first posts and a plurality of second posts on the top surface of the first package substrate and surrounding the at least one lower semiconductor chip;
an underfill layer between the at least one lower semiconductor chip and the first package substrate, surrounding a lower portion of each of the plurality of first posts, and being in contact with an inner wall of the dam structure;
a second package substrate on the plurality of first posts and the plurality of second posts and including a recessed groove in a bottom surface thereof; and
an upper semiconductor chip on the second package substrate,
wherein:
the at least one lower semiconductor chip is vertically below the recessed groove of the second package substrate,
the plurality of first posts are in the region of the top surface of the first package substrate surrounded by the dam structure,
the plurality of first posts electrically connect the first package substrate to the second package substrate, and
the plurality of second posts physically support the second package substrate.

20. The semiconductor package as claimed in claim 19, wherein:
the dam structure is arranged along an edge of the top surface of the first package substrate,
a horizontal width of the dam structure in a direction that is perpendicular to an extension direction of the dam structure is about 20 μm to about 50 μm,
a height of the dam structure in a vertical direction is about 10 μm to about 18 μm,
a height of the recessed groove from the bottom surface of the second package substrate is about 10 μm to about 20 μm, and
a distance between a top surface of the at least one lower semiconductor chip and a bottom of the recessed groove of the second package substrate in the vertical direction is about 40 μm to about 70 μm.
